(19) United States
(12) Patent Application Publication
(10) Pub. No.: US 2017/0275154 A1
(43) Pub. Date: Sep. 28, 2017

(54) Atomic Layer Deposition Layer for a Microelectromechanical system (MEMS) Device

(71) Applicant: Robert Bosch GmbH, Stuttgart (DE)

(72) Inventors: Seow Yuen Yee, Mountain View, CA (US); Ashwin Samarao, Sunnyvale, CA (US); Gary Yama, Mountain View, CA (US)

(21) Appl. No.: 15/470,342

(22) Filed: Mar. 27, 2017

Related U.S. Application Data
(60) Provisional application No. 62/313,456, filed on Mar. 25, 2016.

(51) Int. Cl. B81B 7/00; C23C 16/22; B81C 1/00; C23C 16/455

(52) U.S. Cl. CPC B81B 7/0058; C23C 16/45527; C23C 16/22; B81C 1/0038; B81B 2201/0207; B81B 2201/0214; B81B 2201/0235; B81B 2201/0257; B81B 2201/0292; B81B 2201/047; B81B 2201/0278; B81C 2201/0176

(57) ABSTRACT

System and method for forming an ALD assembly on a surface of a microelectromechanical system (MEMS) device comprises a substrate having a surface and the ALD assembly is at least partially disposed on the surface of the substrate, wherein the ALD assembly is at least one of hydrophobic and hydrophilic properties. The ALD layer further includes a first ALD and a second ALD. On the surface of the substrate, the first ALD is deposited in a first deposition cycle and the second ALD is deposited in a second deposition cycle. The ALD assembly further comprises a seed layer formed using atomic layer deposition and the ALD layer is at least partially disposed on the seed layer. In one example, the seed layer is formed from alumina (Al₂O₃) and the ALD layer is formed from platinum (Pt). In alternate embodiment, on the seed layer, the first ALD is deposited in a first deposition cycle and the second ALD is deposited in a subsequent deposition cycle. The substrate is formed from silicon dioxide (SiO₂).

### CROSS-REFERENCE TO RELATED APPLICATIONS

This application claims the benefit of U.S. Provisional Application No. 62/313,456, filed Mar. 25, 2016, which is incorporated herein by reference.

### FIELD OF DISCLOSURE

This application relates generally to microelectromechanical system (MEMS) devices, particularly to a MEMS device with an atomic layer deposition (ALD) assembly.

### SUMMARY

A summary of certain embodiments disclosed herein is set forth below. It should be understood that these aspects are presented merely to provide the reader with a brief summary of these certain embodiments and that these aspects are not intended to limit the scope of this disclosure. Indeed, this disclosure may encompass a variety of aspects that may not be set forth below.

Embodiments of the disclosure related to systems and methods for forming an ALD assembly on a surface with different characteristics of wettability. For example, a microelectromechanical system (MEMS) device comprises a substrate having a surface and the ALD assembly is at least partially disposed on the surface of the substrate, wherein the ALD assembly is at least one of hydrophobic or hydrophilic. The ALD layer further includes a first ALD and a second ALD. On the surface of the substrate, the first ALD is deposited in a first deposition cycle and the second ALD is deposited in a second deposition cycle. The ALD assembly further comprises a seed layer formed using atomic layer deposition and the ALD layer is at least partially disposed on the seed layer. In one example, the seed layer is formed from alumina (Al₂O₃) and the ALD layer is formed from platinum (Pt). In alternate embodiment, on the seed layer, the first ALD is deposited in a first deposition cycle and the second ALD is deposited in a subsequent deposition cycle. The substrate is formed from silicon dioxide (SiO₂).

In another aspect, the surface of the substrate comprises a first region and a second region. The first region is covered by the ALD assembly and a plurality of trenches formed on the second region.

In another exemplary embodiment of the disclosure, an ALD assembly for an apparatus having a substrate comprises an ALD layer at least partially disposed on the substrate. The ALD layer is at least one of hydrophobic or hydrophilic.

### BRIEF DESCRIPTION OF THE DRAWINGS

These and other features, aspects, and advantages of this disclosure will become better understood when the following detailed description of certain exemplary embodiments is read with reference to the accompanying drawings in which like characters represent like arts throughout the drawings, wherein:

FIG. 1 is a cross section view representing a MEMS device with an ALD assembly according to an example of the disclosure;

FIG. 2 is a cross section view representing a MEMS device with an ALD assembly according to another example of the disclosure;

FIGS. 3A, 3B, and 3C illustrate various stages of depositing an assembly on a substrate using ALD according to a described example of the disclosure;

FIGS. 4A, 4B, 4C, and 4D illustrate various stages of depositing an assembly on a substrate using ALD according to another described example of the disclosure;

FIGS. 5A, 5B, 5C, and 5D illustrate various stages of depositing an assembly on a substrate using ALD according to another described example of the disclosure;

FIGS. 6A, 6B, 6C, and 6D illustrate various stages of depositing an assembly on a substrate using ALD according to another described example of the disclosure; and

FIGS. 7A, 7B, 7C, 7D, 7E, and 7F illustrate various stages of depositing an assembly on a substrate using ALD according to another described example of the disclosure.

DETAILED DESCRIPTION OF SPECIFIC EMBODIMENTS

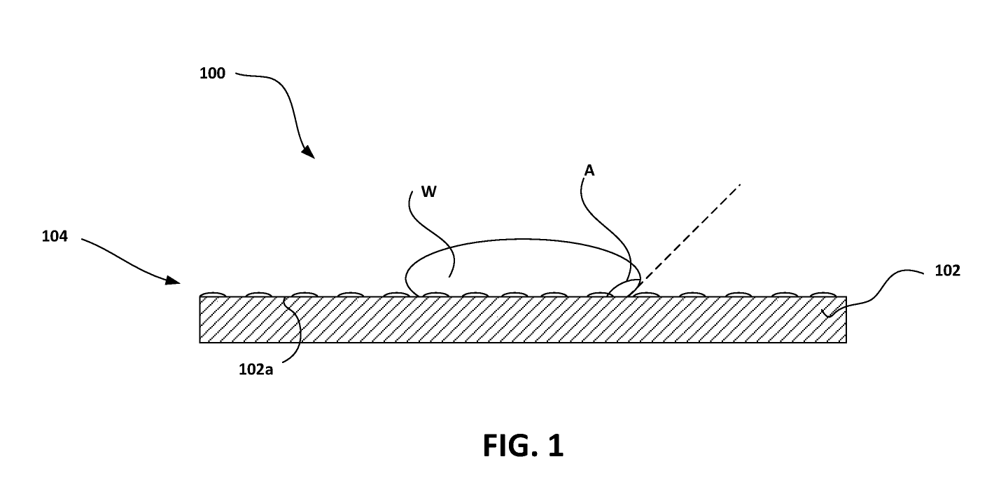

FIG. 1 illustrates an exemplary embodiment of a MEMS device 100. The device 100 includes a support or a substrate 102 and an assembly 104 at least partially disposed on the substrate 102 using ALD. The substrate 102 may be formed from any number of different substrate materials. In some embodiments, the substrate 102 may be formed from an oxides, semiconductors, nitrides, metals, or any suitable material. In an example embodiment, the substrate 102 is formed from silicon dioxide. The thickness of the substrate 102 can vary depending on the application. For example, the thickness of the substrate 102 may be less than or equal to 925 μm. The ALD assembly 104 may be formed from a metal, a single element, an oxide of a single element, a composite oxide, a nitride of a single element, a composite nitride, or any suitable material. In an example embodiment, the ALD assembly 104 is formed from platinum (Pt). The MEMS device 100 may include a microphone, a speaker, a receiver, a pressure sensor, an accelerometer, an environmental sensor, a motion sensor, a thermal sensor, a transducer, a semiconductor, a bolometer, or any suitable device.

ALD utilizes sequential, self-limiting surface reactions of chemical species to either deposit thin films or create thin coatings onto the substrate on a layer-by-layer basis, thus, ALD growth makes atomic scale deposition control possible. Generally, ALD reactions use two chemicals, also referred as precursors to form these films or coatings one at a time. Film growth is controlled by exposing the precursors to a growth surface repeatedly. A first precursor or reactant can be directed over the substrate, with at least some of the first precursor either chemisorbing or physisorbing on the surface of the substrate to form a self-limiting monolayer. Once a monolayer of the first reactant or precursor is formed then the introduction of a second reactant or precursor, in an example embodiment, either simply converts the first reactant to a layer of some desired solid material or reacts with the monolayer of the first precursor. Thermal energy can be provided to the substrate to activate surface reactions between the first and second precursors to form a film layer. During the ALD processes, a purge gas can be introduced to remove non-reacted precursors or excess precursors. This completes one deposition cycle. The cycle may be repeated as many times as desired to form a film or a coating of a suitable thickness and give the surface of the substrate either hydrophobic characteristics or hydrophilic characteristics. To grow a film or a coating using ALD, the substrate can be placed in a reaction chamber where process conditions, including temperature, pressure, amount of precursors, and purging times can be adjusted or controlled to meet the requirements of chemistry and the substrate materials.

Back to FIG. 1, a surface 102a of the substrate 102 is exposed to a reactant and the growth of the ALD assembly 104 progressed on the surface 102a and created a characteristic of wettability. In order to measure the characteristics of the surface either hydrophobic or hydrophilic, a drop of water W on the surface of the ALD assembly 104 is provided. A wetting angle A of the water drop W with respect to a surface of the ALD assembly is one measure of hydrophobicity. As can be seen, the water contact angle A on the surface of the Pt-SiO₂ indicates that the surface becomes hydrophobic. The surface of the Pt-SiO₂ can be more hydrophobic if the substrate 102 continues to be exposed to the reactant and the growth of the ALD assembly continues to progress in subsequent deposition cycles and terminates the process before the ALD assembly forms into a continuous layer.

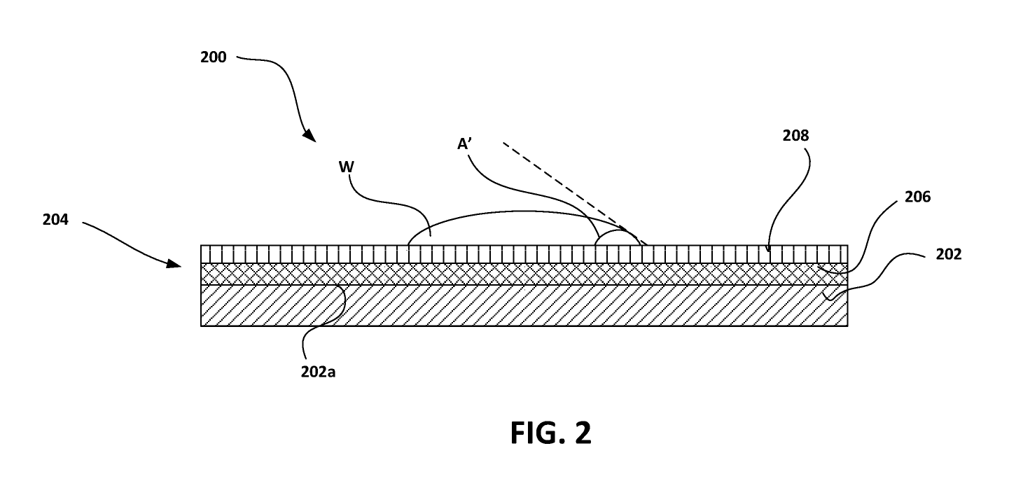

FIG. 2 illustrates another exemplary embodiment of a MEMS device 200. The device 200 includes a support or a substrate 202 and an assembly 204 at least partially disposed on the substrate 202 using ALD. The substrate 202 may be formed from any number of different substrate materials. In some embodiments, the substrate 202 may be formed from an oxides, semiconductors, nitrides, metals, or any suitable material. In an example embodiment, the substrate 202 is formed from silicon dioxide. Depending on the application, other suitable materials such as silicon wafer, stainless steel, etc may suffice. The thickness of the substrate 202 can vary depending on the application. If the substrate is formed from silicon wafer, the thickness of the substrate may be less than or equal to 925 μm. In another example, the substrate comprises deposited layers which may have a thickness that is less than or equal to 2 μm. The ALD assembly 204 may be formed from a metal, a single element, an oxide of a single element, a composite oxide, a nitride of a single element, a composite nitride, or any suitable material. Unlike from the ALD assembly 104 illustrated in FIG. 1, the ALD assembly 204 includes a seed layer 206 and a layer 208 at least partially disposed on the seed layer 206 which in turn at least partially disposed on a surface 202a of the substrate 202 via ALD. In an example embodiment, the seed layer 206 is formed from alumina (Al₂O₃) and the ALD layer 208 is formed from platinum (Pt). The MEMS device 200 may include a microphone, a speaker, a receiver, a pressure sensor, an accelerometer, an environmental sensor, a motion sensor, a thermal sensor, a transducer, a semiconductor, a bolometer, or any suitable device.

As can be seen in FIG. 2, the seed layer 206 is selectively deposited on at least a portion of a surface 202a of the substrate 202 via ALD. After the seed layer 206 has been deposited, the layer 208 is deposited on at least a portion of the seed layer 206 via ALD in first deposited cycle. Additional ALD layer 208 is deposited on subsequent cycle until a suitable thickness and created a surface with hydrophilic characteristics. A drop of water W on a surface of the ALD assembly 204 is provided. A wetting angle A′ of the water drop W with respect to the surface of the ALD assembly is one measure of hydrophilicity. Which is to say, the characteristics of the surface either hydrophobic or hydrophilic is determined by measuring the contact angle A′ between the water drop W and the surface. To form the surface on the substrate 202 with hydrophilic characteristics, the substrate 202 can be subjected to subsequent deposition cycles until a suitable thickness and give the surface of the substrate more hydrophilic characteristics.

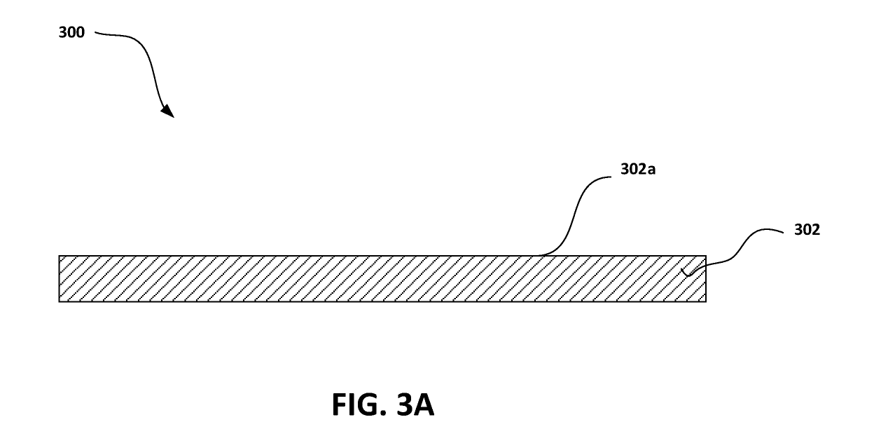

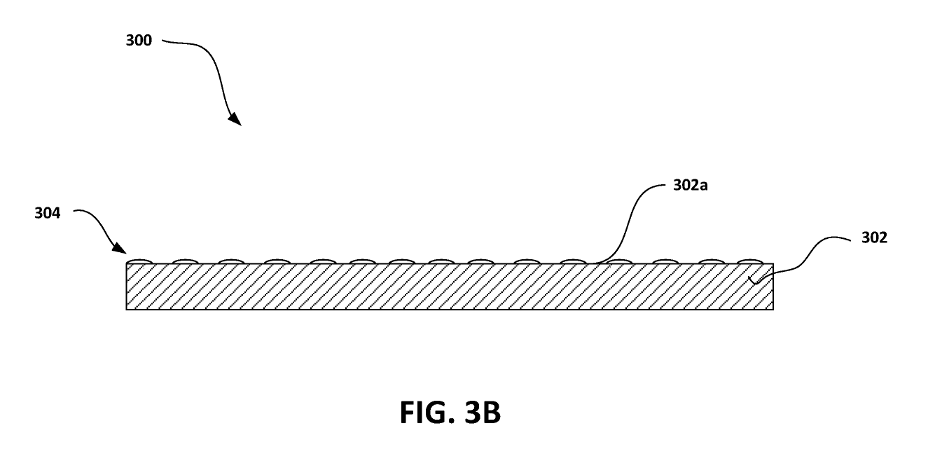

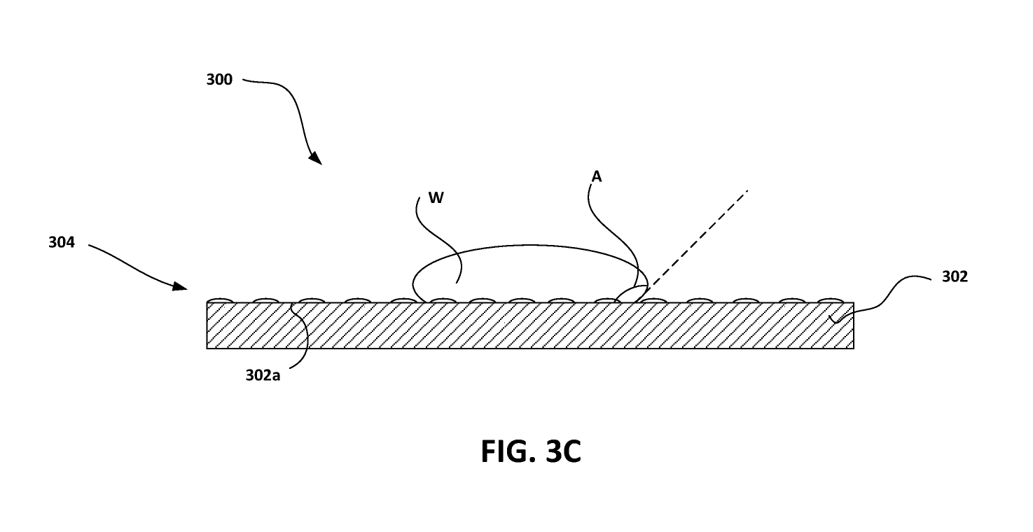

FIGS. 3A, 3B, and 3C illustrate various stages of depositing an assembly on a substrate using ALD in accordance to an exemplary embodiment of the disclosure. A substrate 302 includes a surface 302a, is illustrated in FIG. 3A. The substrate 302 may be formed from any number of different substrate materials. The substrate 302 can have various thickness depending on the application. In some embodiments, the substrate 302 is made from a single material. In another embodiments, the substrate 302 may include multiple layers and each layer is formed from different materials. An assembly 304, as illustrated in FIG. 3B, is at least partially disposed on a surface 302a of the substrate 302 using ALD. The ALD assembly 304 may be formed from a metal, a single element, an oxide of a single element, a composite oxide, a nitride of a single element, a composite nitride, or any suitable material. In an example embodiment, the ALD assembly 304 is formed from platinum (Pt). Other suitable materials may be used as the ALD assembly for growing on the substrate 302. In one embodiment, the ALD assembly 304 may include a single layer. In some embodiments, the ALD assembly 304 may include multiple layers either formed from same material or different materials.

To grow films or coatings using ALD, the substrate 302 can be placed in a reaction chamber where process conditions, including temperature, pressure, amount of precursors, and purging times can be adjusted or controlled to meet the requirements of chemistry and the substrate materials. As an example, the ALD assembly 304 includes a first ALD and a second ALD. The first ALD is deposited on the substrate 302 in a first deposited cycle and the second ALD is deposited in a second deposited cycle. A third or more ALD may be repeatedly deposited in subsequent cycles until a desired thickness is obtained and a surface with either hydrophobic or hydrophilic characteristics is created. To form the surface with desirable characteristics of choice, the substrate 302 may undergo additional number of deposition cycles. As the growth of the ALD assembly 304 progresses on the substrate 302, the surface 302a becomes more hydrophobic and once a desired characteristics of the surface is achieved, the deposited cycle is terminated. This completes the ALD process.

In order to measure or test the characteristics of the surface either hydrophobic or hydrophilic, simply drop of water W on the surface of the ALD assembly 304, as illustrated in FIG. 3C. A wetting angle A of the water drop W with respect to a surface of the ALD assembly is one measure of hydrophobicity. As can be seen, the water contact angle A on the surface of the Pt-SiO₂ indicates that the surface becomes hydrophobic.

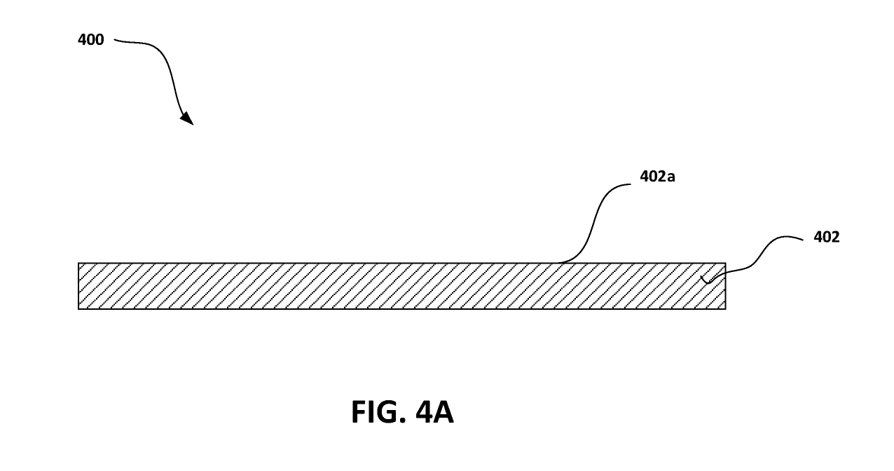

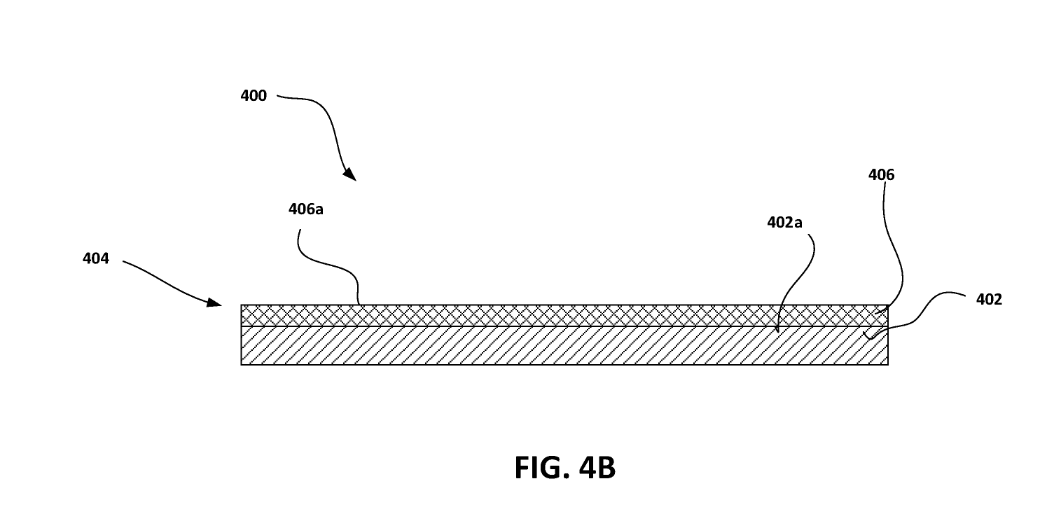

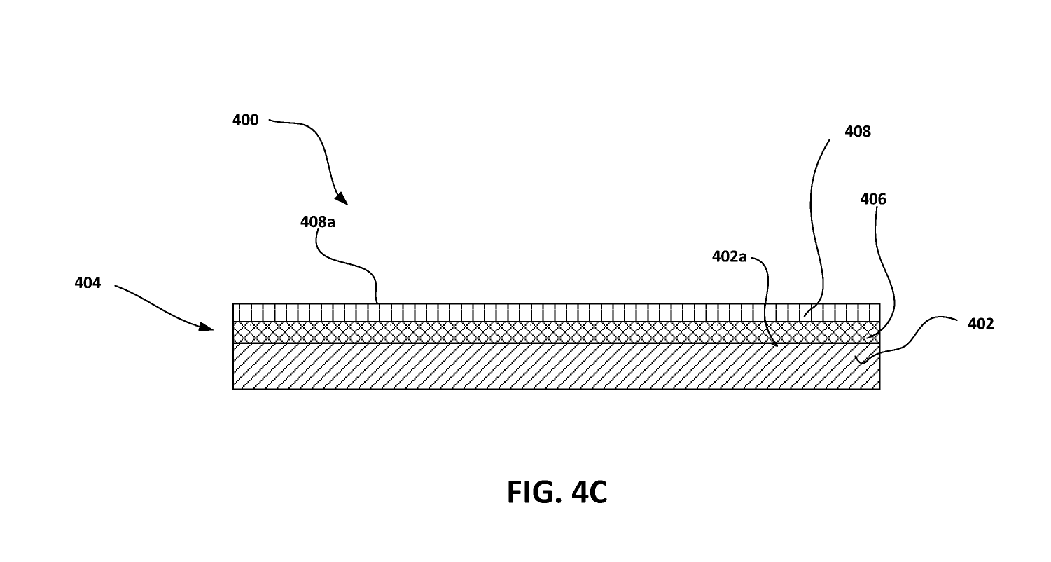

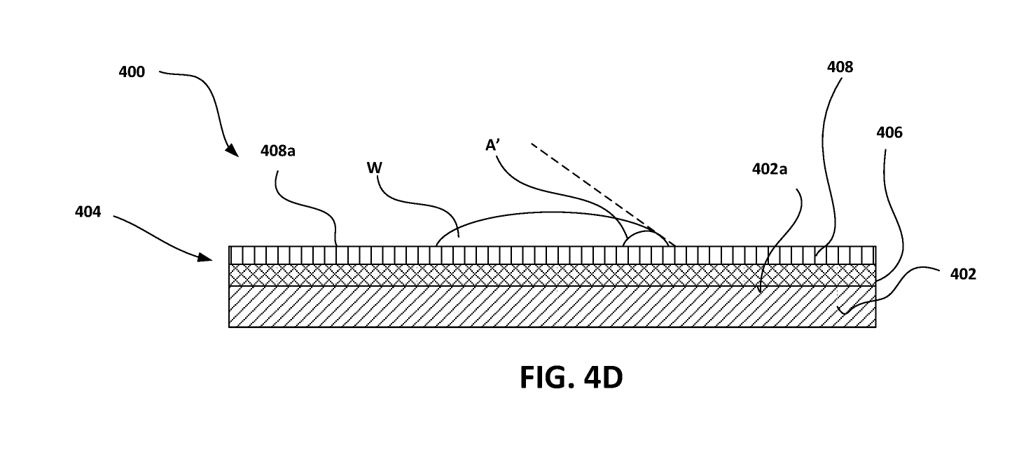

FIGS. 4A, 4B, 4C, and 4D illustrate various stages of depositing an assembly on a substrate using ALD in accordance to another exemplary embodiment of the disclosure. The substrate 402 is identical to the substrate 302 depicted in FIG. 3A and is also formed from SiO₂. Unlike from the assembly 304 illustrated in FIGS. 3B and 3C, an assembly 404 depicted in FIGS. 4B and 4C includes a seed layer 406 disposed on the substrate using ALD. To grow films or coatings using ALD, the substrate 402 can be placed in a reaction chamber where process conditions, including temperature, pressure, amount of precursors, and purging times can be adjusted or controlled to meet the requirements of chemistry and the substrate materials. In preparing a hydrophilic surface, the assembly 404 further includes a layer 408 is at least partially grown on the seed layer 406 using ALD. In an example, the seed layer 406 is formed from alumina (Al₂O₃) and the layer 408 is formed from platinum (Pt). Other suitable materials may be used to deposit on the substrate 402, depending on the application. Since the alumina seed layer 406 has atomically smooth surface profile, it ensures that Pt ALD layer 408 is formed with minimum number of structural defects, resulting in automatically smooth surface morphologies. The Pt ALD layer 408 has a surface 408a to be hydrophilic. To form the surface with hydrophilic characteristics, the substrate 402 may undergo additional number of deposition cycles. As the growth of the ALD assembly 404 on the substrate 402 progresses, the surface 408a becomes hydrophilic and once a desired characteristics of the surface is achieved, the deposited cycle is terminated. This completes the ALD process.

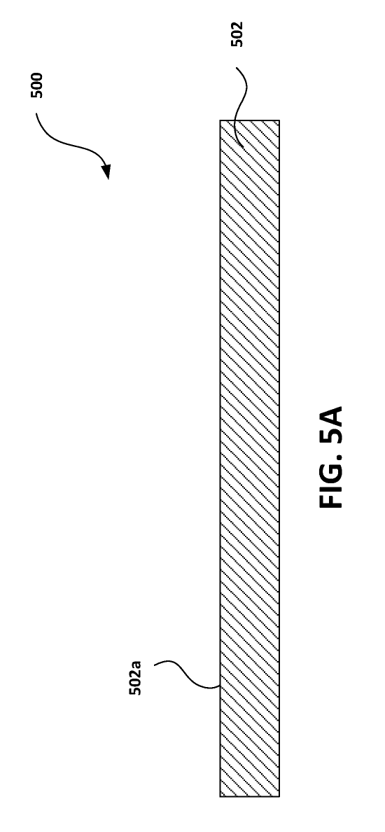

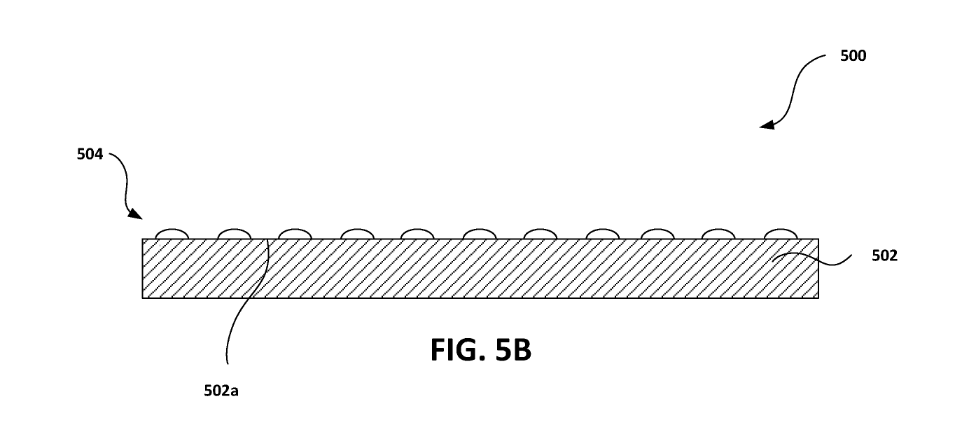

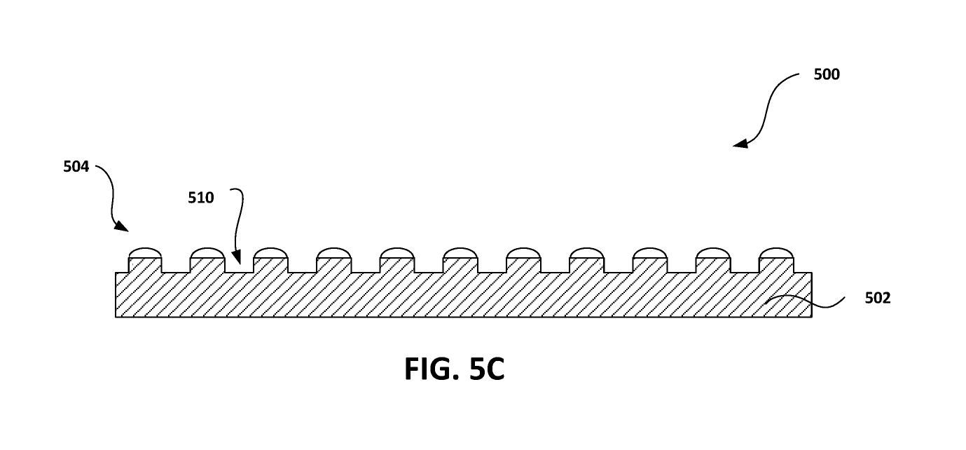

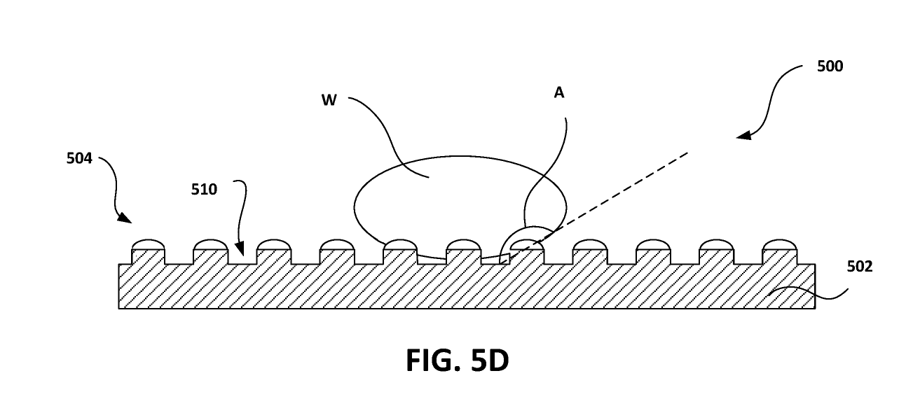

FIGS. 5A, 5B, 5C, and 5D illustrate various stages of depositing an assembly on a substrate using ALD in accordance to an exemplary embodiment of the disclosure. Unlike from the MEMS device 300 of FIG. 3C, MEMS device 500 includes trenches 510 formed on the substrate 502 which will be described in greater detail below. The substrate 502 includes a surface 502a as depicted in FIG. 5A. The substrate 502 may be formed from any number of different substrate materials. The substrate 502 can have various thickness depending on the application. In some embodiments, the substrate 502 is made from single material. In another embodiments, the substrate 502 may include multiple layers and each layer is formed from different materials. An assembly 504, in the form of island shape, is at least partially deposited on the surface 502a of the substrate 502 using ALD. As illustrated in FIG. 5B, The ALD assembly 504 includes a plurality of island and each island is independent from each other, thus is not linked together. The ALD assembly 504 may be formed from a metal, a single element, an oxide of a single element, a composite oxide, a nitride of a single element, a composite nitride, or any suitable material. In an example embodiment, the ALD assembly 504 is formed from platinum (Pt). Other suitable materials may be used for growing on the substrate 502 to form the ALD assembly 504. In one embodiment, the ALD assembly 504 may include a single layer. In some embodiments, the ALD assembly 504 may include multiple layers either formed from same material or different materials.

To grow films or coatings using ALD, the substrate 502 is placed in a reaction chamber where process conditions, including temperature, pressure, amount of precursors, and purging times can be adjusted or controlled to meet the requirements of chemistry and the substrate materials. As an example, Pt is deposited on the substrate 502 in a deposited cycle. The substrate 502 may continue to undergo the ALD process by growing Pt on the surface 502a in subsequent cycles. As the growth of the ALD assembly 504 progresses on the substrate 502, the surface 502a becomes more hydrophobic and once a desired characteristics of the surface is achieved, the deposited cycle is terminated. This completes the ALD process.

As can be seen on FIG. 5B, a plurality of islands, independent from each other and are not linked to each other, are formed on the substrate 502a leaving a portion of the substrate 502a exposed to the environment. To enhance the hydrophobicity characteristic of the surface 502a, the ALD assembly 504 is served as a mask for etching of its underlying layer and to achieve a high-fidelity transfer of the resist patterns. The MEMS device 500 undergoes an anisotopic etching process to remove a portion of the substrate located at the exposed surface 502a that are not coated with the ALD assembly 504. As illustrated in FIG. 5C, trenches 510 are formed between the islands. In one embodiment, the anisotopic etching is reactive ion etching (RIE). In another embodiment, a deep reactive ion etching (DRIE) may be formed on the surface 502a of the substrate 502 to form either deep trenches or desirable trenches with certain depth. Other suitable etching process may be performed on the substrate 502, depending on the application.

To measure the characteristics of the surface, simply apply a drop of water W on the surface of the ALD assembly 504, as shown in FIG. 5D. A wetting angle A of the water drop W with respect to a surface of the ALD assembly is one measure of hydrophobicity. As can be seen, the water contact angle A on the surface of the Pt-SiO₂ indicates the contact angle A is greater than 90 degree, therefore, the surface is hydrophobic.

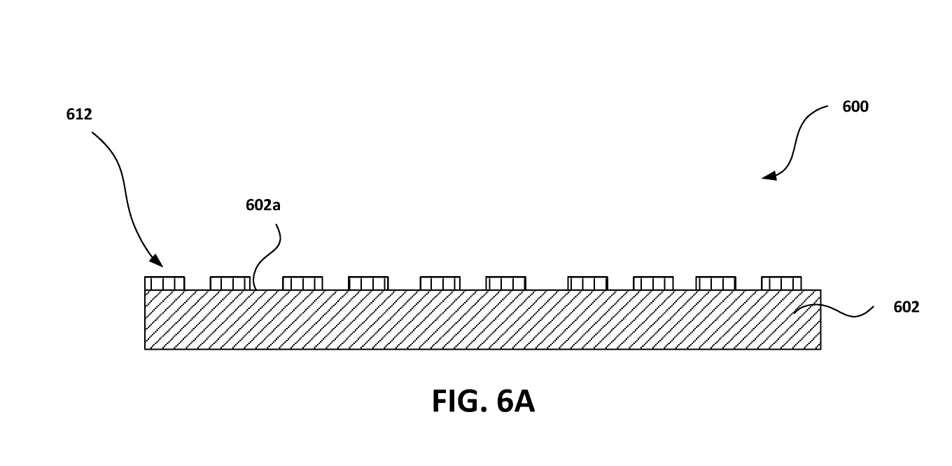

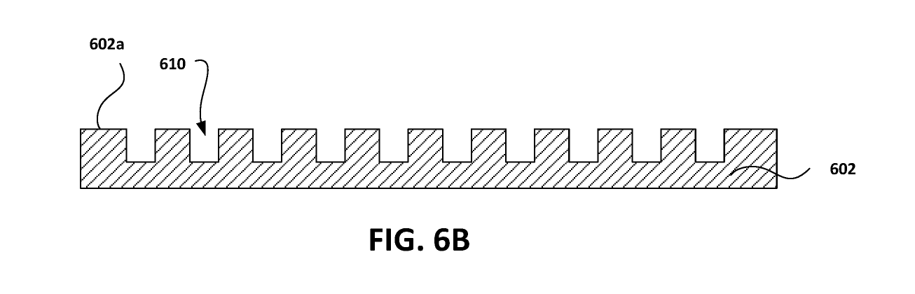

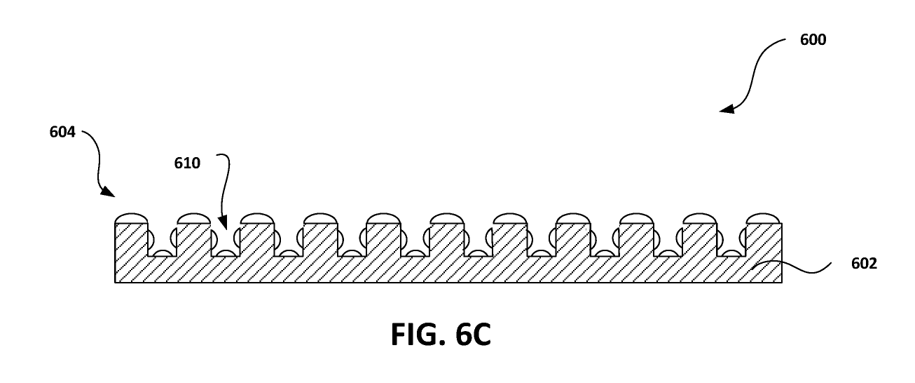

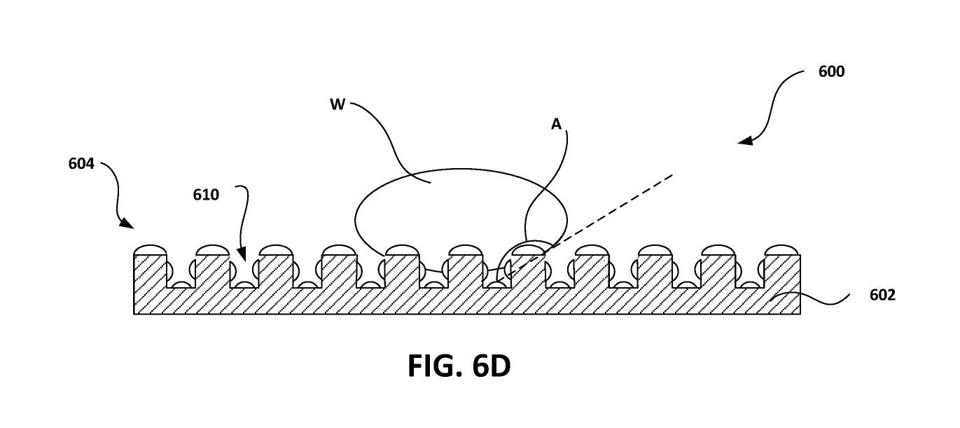

FIGS. 6A, 6B, 6C, and 6D illustrate various stages of depositing an assembly 604 on a substrate 602 using ALD in accordance to an exemplary embodiment of the disclosure. Unlike from the MEMS device 500 of FIGS. 5A, 5B, 5C, and 5D, MEMS device 600 includes trenches 610 formed on the substrate 602 prior to depositing the assembly 604 on a surface 602a of the substrate 602 using ALD which will be described in greater below. The substrate 602 may be formed from any number of different substrate materials. The substrate 602 may have various thickness depending on the application. In some embodiments, the substrate 602 is made from single material. In another embodiments, the substrate 602 may include multiple layers and each layer is formed from different materials. As depicted in FIG. 6A, a resist pattern is defined by a lithographic process to serve as a masking tape or a sacrificial layer 612 is disposed on the surface 602a of the substrate 602. To form a plurality of trenches 610 on the surface 602a, the MEMS device 600 undergoes an etching process so that a portion of the substrate that is not covered by the masking tape or the sacrificial layer 612 is removed. Once a plurality of trenches 610 are formed, as depicted in FIG. 6B, the MEMS device 600 undergoes a suitable process to remove the masking tape or the sacrificial layer 612 and exposes a portion of surface beneath the masking tape 612. An assembly 604, in the form of island shape, is deposited on the entire surface 602a and the trenches 610 of the substrate 602 using ALD. As illustrated in FIG. 6C, the ALD assembly 604 includes a plurality of island and each island independent from each other, thus is not linked together. The ALD assembly 604 may be formed from a metal, a single element, an oxide of a single element, a composite oxide, a nitride of a single element, a composite nitride, or any suitable material. In an example embodiment, the ALD assembly 604 is formed from platinum (Pt). Other suitable materials may be used for growing on the substrate 602 to form the ALD assembly 604. In one embodiment, the ALD assembly 604 may include a single layer. In some embodiments, the ALD assembly 604 may include multiple layers either formed from same material or different materials.

To grow films or coatings using ALD, the substrate 602 can be placed in a reaction chamber where process conditions, including temperature, pressure, amount of precursors, and purging times can be adjusted or controlled to meet the requirements of chemistry and the substrate materials. As an example, Pt is deposited on the surfaces 602a and the trenches 610 in a deposited cycle. The substrate 602 may continue to undergo the ALD process by growing Pt on the surface 602a and the trenches 610 in subsequent cycles. As the growth of the ALD assembly 604 progresses on the substrate 602, the surface 602a and the trenches 610 become more hydrophobic and once a desired characteristics of the surface is achieved, the deposited cycle is terminated. This completes the ALD process. As can be seen on FIG. 6C, a plurality of islands, independent from each other and are not linked together, are formed on the surface 602a and the trenches 610 of the substrate 602a, thus enhances the hydrophobic characteristic of the MEMS device 600.

To measure the characteristics of the surface, simply apply a drop of water W on the surface of the ALD assembly 604, as shown in FIG. 6D. A wetting angle A of the water drop W with respect a surface of the ALD assembly is one measure of hydrophobicity. As can be seen, the water contact angle A on the surface of the Pt-SiO₂ indicates the contact angle A is greater than 90 degree, therefore, the surface is hydrophobic.

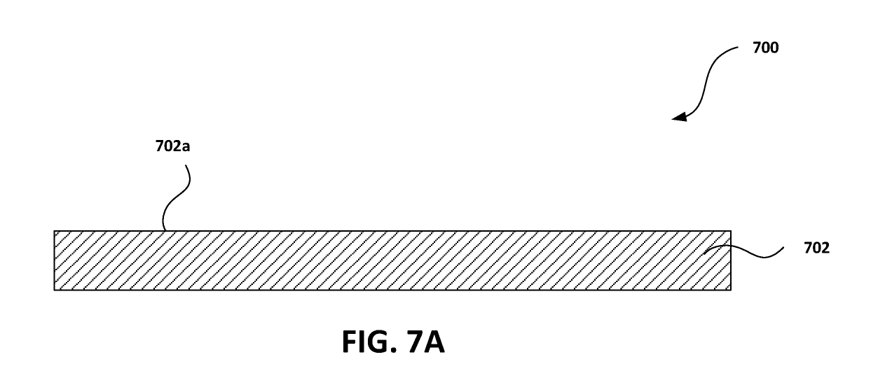

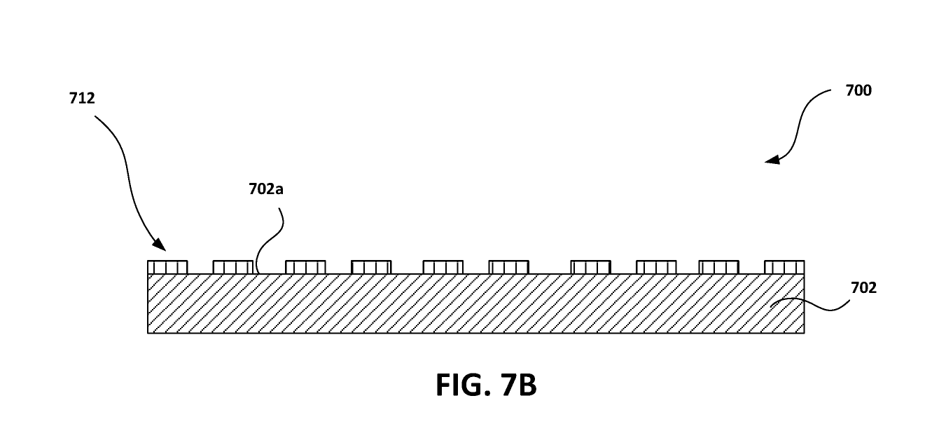

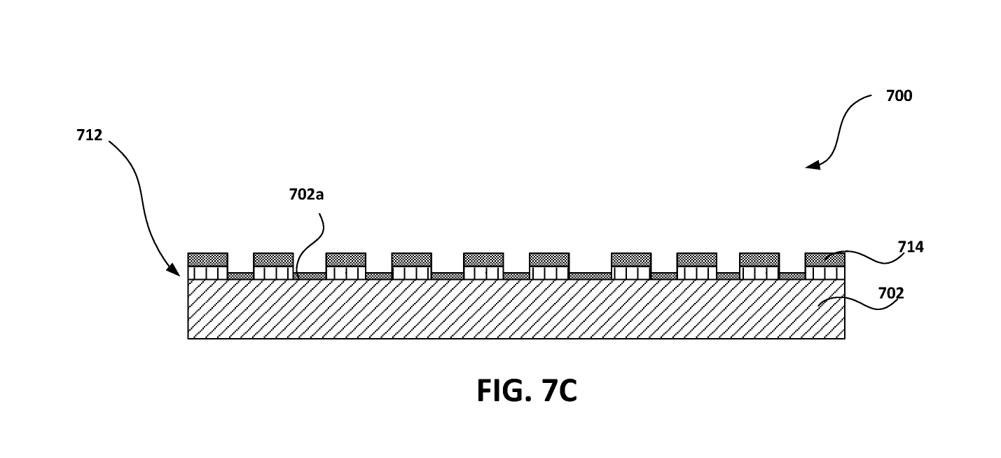

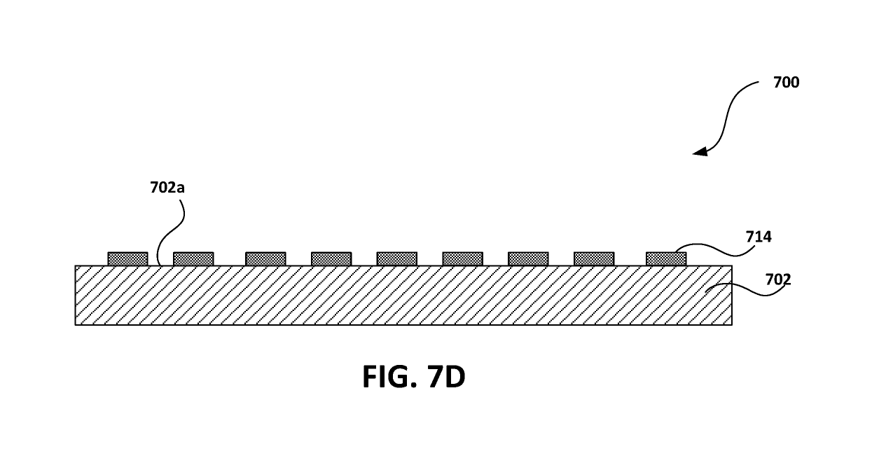

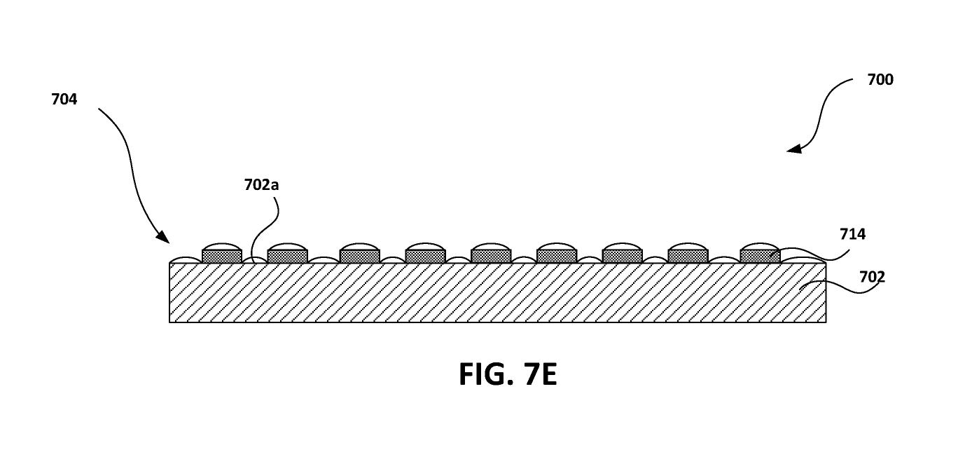

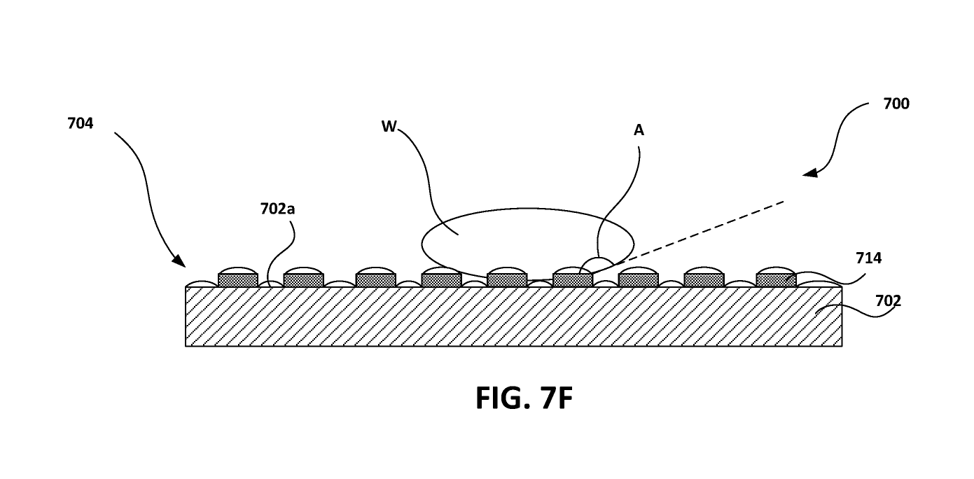

FIGS. 7A, 7B, 7C, 7D, 7E, and 7F illustrate various stages of depositing an assembly 704 on a substrate 702 using ALD in accordance to an exemplary embodiment of the disclosure. Unlike from the MEMS device 600 of FIGS. 6A, 6B, 6C, and 6D wherein the unexposed resist is removed, i.e. negative resist, MEMS device 700 is treated under a positive resist, also referred as liftoff technique, to form a resist pattern on the substrate 702. The substrate 702 may be formed from any number of different substrate materials. The substrate 702 may have various thickness depending on the application. In some embodiments, the substrate 702 is made from single material. In another embodiments, the substrate 702 may include multiple layers and each layer is formed from different materials. As depicted in FIG. 7B, a resist pattern is defined by a lithographic process to serve as a masking tape or a sacrificial layer 712 is disposed on the surface 702a of the substrate 702. A film 714 similar to the substrate 602 is deposited over the resist 712 and the substrate 702. Other suitable materials may be used to deposit over the resist 712 and the substrate 702. Those portions of the film 714 on the resist 712 are removed by selectively dissolving the resist layer in an appropriate etchant so that the overlying film is liftoff and removed as depicted in FIG. 7D.

An assembly 704, in the form of island shape, is deposited on the entire surface 702a of the substrate 702 and the film 714. As depicted in FIG. 7E, each island is independent from each other, thus is not linked together. The ALD assembly 704 may be formed from a metal, a single element, an oxide of a single element, a composite oxide, a nitride of a single element, a composite nitride, or any suitable material. In an example embodiment, the ALD assembly 704 is formed from platinum (Pt). Other suitable materials may be used for growing on the substrate 702 and the film 714 to form the ALD assembly 704. In one embodiment, the ALD assembly 704 may include a single layer. In some embodiments, the ALD assembly 704 may include multiple layers either formed from same material or different materials.

To grow films or coatings using ALD, the MEMS device 700 can be placed in a reaction chamber where process conditions, including temperature, pressure, amount of precursors, and purging times can be adjusted or controlled to meet the requirements of chemistry and the substrate materials. As an example, Pt is deposited on the surfaces 702a and the film 714 in a deposited cycle. The MEMS device 700 may continue to undergo the ALD process by growing Pt on the surface 702a and the film 714 in subsequent cycles. As the growth of the ALD assembly 704 progresses on the MEMS device 700, the surface 702a and the film 714 become more hydrophobic and once a desired characteristics of the surface is achieved, the deposited cycle is terminated. This completes the ALD process. As can be seen on FIG. 7F, a plurality of islands, independent from each other and are not linked together, are formed on the surface 702a and the film 714, thus enhances the hydrophobic characteristic of the MEMS device 700.

To measure the characteristics of the surface, simply apply a drop of water W on the surface of the ALD assembly 704, as shown in FIG. 7F. A wetting angle A of the water drop W with respect a surface of the ALD assembly is one measure of hydrophobicity. As can be seen, the water contact angle A on the surface of the Pt-SiO₂ indicates the contact angle A is greater than 90 degree, therefore, the MEMS device 700 is hydrophobic.

The specific embodiments described above have been shown by way of example, and it should be understood that these embodiments may be susceptible to various modifications and alternative forms. It should be further understood that the claims are not intended to be limited to the particular forms disclosed, but rather to cover all modifications, equivalents, and alternatives falling with the sprit and scope of this disclosure.

What is claimed is:

1. A microelectromechanical system (MEMS) device comprising:
a substrate having a surface; and
an atomic layer deposition (ALD) assembly at least partially disposed on the surface of the substrate;
wherein the ALD assembly is at least one of hydrophobic and hydrophilic.

2. The MEMS device of claim 1 wherein the ALD assembly comprising an ALD layer, the ALD layer is at least one of the hydrophobic and hydrophilic.

3. The MEMS device of claim 2 wherein the ALD layer includes a first ALD and a second ALD.

4. The MEMS device of claim 3 wherein on the surface of the substrate, the first ALD is deposited in a first deposition cycle and the second ALD is deposited in a second deposition cycle.

5. The MEMS device of claim 2 wherein the ALD assembly further comprising a seed layer, the ALD layer is at least partially disposed on the seed layer.

6. The MEMS device of claim 5 wherein the seed layer is formed using atomic layer deposition.

7. The MEMS device of claim 5 wherein the seed layer is formed from alumina (Al₂O₃).

8. The MEMS device of claim 5 wherein the ALD layer is formed from platinum (Pt).

9. The MEMS device of claim 5 wherein the ALD layer includes a first ALD and a second ALD;
wherein on the seed layer, the first ALD is deposited in a first deposition cycle and the second ALD is deposited in a subsequent deposition cycle.

10. The MEMS device of claim 1 wherein the substrate is formed from silicon dioxide (SiO₂).

11. The MEMS device of claim 5 wherein the ALD layer is formed from a metal element.

12. The MEMS device of claim 1 wherein the MEMS device is selected from a group consisting of a microphone, a speaker, a receiver, a pressure sensor, a chemical sensor, a gas sensor, an optical sensor, a gyroscope, an accelerometer, an environmental sensor, a motion sensor, a thermal sensor, a transducer, a semiconductor sensor, and a bolometer.

13. The MEMS device of claim 1 wherein the surface of the substrate comprises a first region and a second region, wherein the first region is covered by the ALD assembly.

14. The MEMS device of claim 13 further comprising a plurality of trenches formed on the second region.

15. The MEMS device of claim 1, further comprising a plurality trenches formed on the substrate prior to the ALD assembly is disposed on the surface of the substrate.

16. The MEMS device of claim 15, wherein the ALD is disposed on the surface of the substrate and on the trenches.

17. An atomic layer deposition (ALD) assembly for an apparatus having a substrate comprising:
an ALD layer at least partially disposed on the substrate;
wherein the ALD layer is at least one of hydrophobic and hydrophilic.

18. The ALD assembly of claim 17 wherein the ALD layer includes a first ALD and a second ALD.

19. The ALD assembly of claim 18 wherein on the substrate, the first ALD is deposited in a first deposition cycle and the second ALD is deposited in a second deposition cycle.

20. The ALD assembly of claim 19 wherein the ALD assembly further comprising a seed layer, the seed layer at least partially disposed on the substrate;
wherein at least one of the first or the second ALD is at least partially disposed on the seed layer.

21. The ALD assembly of claim 20 wherein the seed layer is formed using atomic layer deposition.

22. The ALD assembly of claim 21 wherein the seed layer is formed from alumina (Al₂O₃).

23. The ALD assembly of claim 17 wherein the ALD layer is formed from platinum (Pt).
